(19) United States
(12) Patent Application Publication
(10) Pub. No.: US 2025/0320625 A1
(43) Pub. Date: Oct. 16, 2025

(54) MATERIAL FEEDING METHOD, MONOCRYSTALLINE SILICON MANUFACTURING METHOD, MATERIAL FEED CONTROL DEVICE, AND MONOCRYSTALLINE SILICON MANUFACTURING SYSTEM

(71) Applicant: SUMCO CORPORATION, Tokyo (JP)

(72) Inventor: Hiroyuki OOTA, Nagasaki (JP)

(73) Assignee: SUMCO CORPORATION, Tokyo (JP)

(21) Appl. No.: 19/176,842

(22) Filed: Apr. 11, 2025

(30) Foreign Application Priority Data
Apr. 16, 2024 (JP) 2024-066286

(51) Int. Cl. C30B 15/02; C30B 15/20; C30B 29/06

(52) U.S. Cl. CPC C30B 15/02; C30B 15/20; C30B 29/06

(57) ABSTRACT

Provided is a material feeding method of feeding a silicon material into a silicon melt using a material feeder including a charge tube and an open/close unit, the charge tube having a hollow cylindrical shape, the open/close unit opening and closing a lower-end opening of the charge tube. The material feeding method includes: starting feeding of the silicon material, by attaching the material feeder charged with the silicon material to a first end of a wire and lowering the open/close unit with respect to the charge tube to open the lower-end opening to feed the silicon material into the silicon melt; and judging completion of the feeding of the silicon material based on a weight of the material feeder attached to the first end of the wire, to terminate the feeding of the silicon material, the weight being detected by a weight detector.

### CROSS REFERENCE TO RELATED APPLICATIONS

The entire disclosure of Japanese Patent Application No. 2024-066286 filed Apr. 16, 2024 is expressly incorporated by reference herein.

### TECHNICAL FIELD

The present invention relates to a material feeding method, a monocrystalline silicon manufacturing method, a material feed control device, and a monocrystalline silicon manufacturing system.

### BACKGROUND ART

There is a process of melting a silicon material in a crucible to produce a silicon melt before growing monocrystalline silicon. It is effective in terms of cost reduction to increase an amount of the silicon material charged in the crucible as much as possible to increase a length of the monocrystalline silicon to be grown.

However, the amount of the silicon material capable of being charged in a crucible per one batch is restricted by a size of the crucible and the like. Accordingly, it is necessary to feed a new silicon material into the silicon melt after the silicon material charged in the crucible is completely dissolved to produce the silicon melt.

In order to feed the new silicon material into the silicon melt, it has been known to use a material feeder including a quartz charge tube and an open/close unit for opening and closing a lower-end opening of the charge tube (see, for instance, Literature 1: JP 2004-244236 A).

However, Literature 1 does not disclose how feeding completion of the silicon material is to be judged. A conceivable method for judging the feeding completion of the silicon material is for an operator to visually check the material feeder. However, this may increase a workload for monitoring and cause deviation in judgment results depending on the operator's sensory evaluation. In addition, the interior conditions of the charge tube, whose quartz surface is clouded after increased number of usage, are possibly difficult to be visually checked.

### SUMMARY OF THE INVENTION

An object of the invention is to provide a material feeding method, a monocrystalline silicon manufacturing method, a material feed control device, and a monocrystalline silicon manufacturing system that are capable of easily and appropriately judging feeding completion of a silicon material.

A material feeding method according to an aspect of the invention is a material feeding method of feeding a silicon material into a silicon melt in a crucible provided within a chamber using a material feeder, the material feeder including a charge tube and an open/close unit, the charge tube having a hollow cylindrical shape, the open/close unit being configured to open and close a lower-end opening of the charge tube, the material feeding method including: starting feeding of the silicon material, by attaching the material feeder charged with the silicon material to a first end of a wire and lowering the open/close unit with respect to the charge tube to open the lower-end opening to feed the silicon material into the silicon melt; and judging completion of the feeding of the silicon material based on a weight of the material feeder attached to the first end of the wire, to terminate the feeding of the silicon material, the weight being detected by a weight detector.

It is preferable in the material feeding method according to the above aspect of the invention that: the charge tube includes a cylindrical portion provided with the lower-end opening, a closing portion configured to close an upper end of the cylindrical portion, and a protruding portion protruding from an outer circumferential surface of the cylindrical portion or the closing portion; the open/close unit includes a shaft penetrating through the closing portion and having an upper end attached to the first end of the wire, and a bottom cover fixed to a lower end of the shaft and configured to open and close the lower-end opening; the chamber is provided with a charge tube stopper configured to be in contact with a lower end of the protruding portion to restrict a downward movement of the charge tube; and in the starting the feeding, the open/close unit is lowered with respect to the charge tube to open the lower-end opening to feed the silicon material, after the protruding portion is brought into contact with the charge tube stopper.

It is preferable in the material feeding method according to the above aspect of the invention that: the shaft is provided with a bottom cover stopper configured to be in contact with an upper end of the closing portion to restrict a downward movement of the bottom cover with respect to the charge tube; in the starting the feeding, the open/close unit is lowered to feed the silicon material after the protruding portion is brought into contact with the charge tube stopper until the bottom cover stopper is in contact with the closing portion; in the judging the completion of the feeding to terminate the feeding, the open/close unit is raised until the bottom cover stopper separates from the closing portion and the protruding portion separates from the charge tube stopper and the feeding of the silicon material is judged to be completed when a detection result of the weight detected by the weight detector matches a predetermined weight; and the predetermined weight is a self-weight of the material feeder.

It is preferable in the material feeding method according to the above aspect of the invention that: in the judging the completion of the feeding to terminate the feeding, the feeding of the silicon material is judged to be completed when a detection result of the weight detected by the weight detector matches a predetermined weight while the open/close unit is not raised; and the predetermined weight is a self-weight of the open/close unit.

It is preferable in the material feeding method according to the above aspect of the invention that, when the detection result of the weight does not match the predetermined weight in the judging the completion of the feeding to terminate the feeding, the judging the completion of the feeding to terminate the feeding is performed, after performing an open/close unit vertical movement in which the open/close unit is upwardly and downwardly moved.

It is preferable in the material feeding method according to the above aspect of the invention that occurrence of a trouble is reported when the detection result of the weight does not match the predetermined weight even after performing each of the judging the completion of the feeding to terminate the feeding and the open/close unit vertical movement for a predetermined number of times.

It is preferable in the material feeding method according to the above aspect of the invention that: a drum configured to be rotated by driving of a motor to wind or unwind the wire is fixed to a second end of the wire; the weight detector is a load cell configured to detect a load applied on the motor to detect the weight of the material feeder attached to the first end of the wire; and in the starting the feeding and the judging the completion of the feeding to terminate the feeding, the motor is controlled to move the material feeder.

A monocrystalline silicon manufacturing method according to another aspect of the invention includes: feeding the silicon material into the silicon melt by the material feeding method according to the above-described aspect of the invention; and growing monocrystalline silicon using the silicon melt by CZ method.

A material feed control device according to still another aspect of the invention is configured to feed a silicon material into a silicon melt in a crucible provided within a chamber using a material feeder, the material feeder including a charge tube and an open/close unit, the charge tube having a hollow cylindrical shape, the open/close unit being configured to open and close a lower-end opening of the charge tube, the material feed control device including: a feed start controller configured to lower the open/close unit of the material feeder, which is charged with the silicon material and attached to a first end of a wire, with respect to the charge tube to open the lower-end opening to feed the silicon material into the silicon melt; and a feed termination controller configured to judge completion of feeding of the silicon material based on a weight of the material feeder attached to the first end of the wire, the weight being detected by a weight detector.

It is preferable in the material feed control device according to the above aspect of the invention that: the charge tube includes a cylindrical portion provided with the lower-end opening, a closing portion configured to close an upper end of the cylindrical portion, and a protruding portion protruding from an outer circumferential surface of the cylindrical portion or the closing portion; the open/close unit includes a shaft penetrating through the closing portion and having an upper end attached to the first end of the wire, and a bottom cover fixed to a lower end of the shaft and configured to open and close the lower-end opening; the chamber is provided with a charge tube stopper configured to be in contact with a lower end of the protruding portion to restrict a downward movement of the charge tube; and the feed start controller is configured to lower the open/close unit with respect to the charge tube to open the lower-end opening to feed the silicon material, after the protruding portion is brought into contact with the charge tube stopper.

It is preferable in the material feed control device according to the above aspect of the invention that: the shaft is provided with a bottom cover stopper configured to be in contact with an upper end of the closing portion to restrict a downward movement of the bottom cover with respect to the charge tube; the feed start controller is configured to lower the open/close unit to feed the silicon material after the protruding portion is brought into contact with the charge tube stopper until the bottom cover stopper is in contact with the closing portion; the feed termination controller is configured to raise the open/close unit until the bottom cover stopper separates from the closing portion and the protruding portion separates from the charge tube stopper and judge that the feeding of the silicon material is completed when a detection result of the weight detected by the weight detector matches a predetermined weight; and the predetermined weight is a self-weight of the material feeder.

It is preferable in the material feed control device according to the above aspect of the invention that: the feed termination controller is configured to judge that the feeding of the silicon material is completed when a detection result of the weight detected by the weight detector matches a predetermined weight while the open/close unit is not raised; and the predetermined weight is a self-weight of the open/close unit.

It is preferable in the material feed control device according to the above aspect of the invention that, when judging that the detection result of the weight does not match the predetermined weight, the feed termination controller performs judgment of whether the feeding of the silicon material is completed based on the detection result of the weight, after performing an open/close unit vertical movement in which the open/close unit is upwardly and downwardly moved.

It is preferable in the material feed control device according to the above aspect of the invention that the feed termination controller is configured to report occurrence of a trouble when the detection result of the weight does not match the predetermined weight even after performing each of the judgment of whether the feeding of the silicon material is completed and the open/close unit vertical movement for a predetermined number of times.

It is preferable in the material feed control device according to the above aspect of the invention that: a drum configured to be rotated by driving of a motor to wind or unwind the wire is fixed to a second end of the wire; the weight detector is a load cell configured to detect a load applied on the motor to detect the weight of the material feeder attached to the first end of the wire; and the feed start controller and the feed termination controller are configured to control the motor to move the material feeder.

A monocrystalline silicon manufacturing system according to further aspect of the invention includes: the material feed control device according to the above aspect of the invention; the material feeder; the wire attached with the material feeder or a seed crystal at the first end; the weight detector; and a growth controller configured to bring the seed crystal attached to the first end of the wire into contact with the silicon melt and then pull up the seed crystal to grow monocrystalline silicon by CZ method.

Another monocrystalline silicon manufacturing system according to still further aspect of the invention includes: the material feed control device according to the above aspect of the invention; the material feeder; a pulling drive unit including the wire attached with the material feeder or a seed crystal at the first end, the drum, and the motor; the load cell; and a growth controller configured to bring the seed crystal attached to the first end of the wire into contact with the silicon melt and then pull up the seed crystal to grow monocrystalline silicon by CZ method.

### BRIEF DESCRIPTION OF DRAWINGS

FIG. 1 schematically illustrates a monocrystalline silicon manufacturing system according to first and second exemplary embodiments, in which monocrystalline silicon is being grown.

FIG. 2 schematically illustrates the monocrystalline silicon manufacturing system according to the first and second exemplary embodiments, in which a silicon material is being fed.

FIG. 3A is a vertical cross sectional view illustrating a material feeder according to the first exemplary embodiment, in which a lower-end opening of a charge tube is closed.

FIG. 3B is a vertical cross sectional view illustrating the material feeder according to the first exemplary embodiment, in which the lower-end opening of the charge tube is opened.

FIG. 4 is a flowchart of a monocrystalline silicon manufacturing method according to the first and second exemplary embodiments.

FIG. 5 is a flowchart of a material feeding step according to the first exemplary embodiment.

FIG. 6 is a graph illustrating a relationship between time and a weight detected by a load cell in the material feeding step according to the first exemplary embodiment.

FIG. 7 is an illustration of the material feeding step according to the first exemplary embodiment.

FIG. 8 is a flowchart of the material feeding step according to the first and second exemplary embodiments.

FIG. 9A is a vertical cross sectional view illustrating a material feeder according to the second exemplary embodiment, in which a lower-end opening of a charge tube is closed.

FIG. 9B is a vertical cross sectional view illustrating the material feeder according to the second exemplary embodiment, in which the lower-end opening of the charge tube is opened.

FIG. 10 is a flowchart of a material feeding step according to the second exemplary embodiment.

FIG. 11 is a graph illustrating a relationship between time and a weight detected by a load cell in the material feeding step according to the second exemplary embodiment.

FIG. 12 is an illustration of the material feeding step according to the second exemplary embodiment.

### DETAILED DESCRIPTION

### First Exemplary Embodiment

### Arrangement of Monocrystalline Silicon Manufacturing System

Initially, an arrangement of a monocrystalline silicon manufacturing system according to a first exemplary embodiment of the invention will be described below.

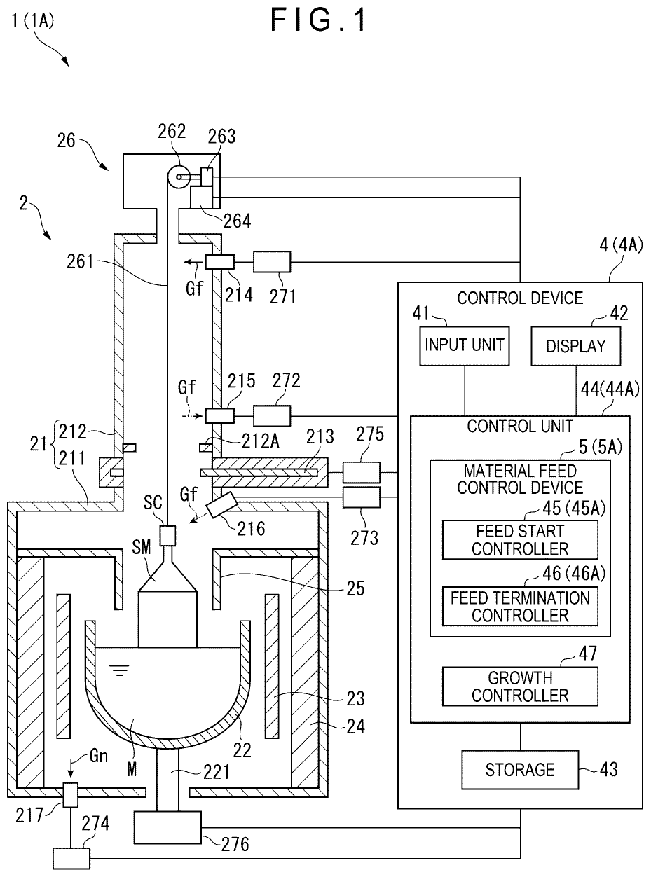

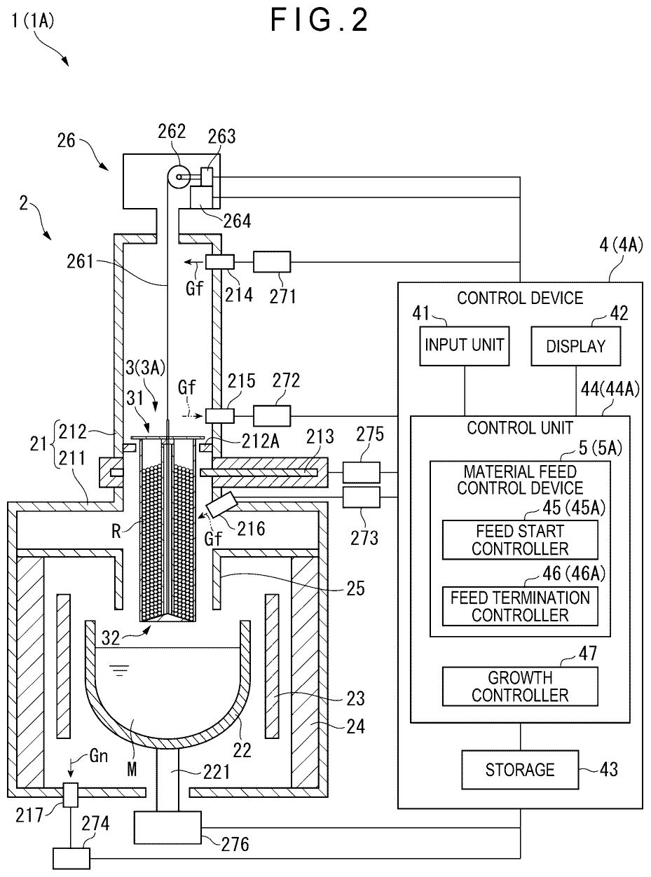

A monocrystalline silicon manufacturing system 1 illustrated in FIGS. 1 and 2 includes a monocrystalline silicon manufacturing apparatus 2.

The monocrystalline silicon manufacturing apparatus 2 is configured to manufacture monocrystalline silicon (ingot) SM added with a volatile dopant by Czochralski (CZ) method. Examples of the volatile dopant include arsenic, red phosphorus, and antimony. The monocrystalline silicon manufacturing apparatus 2 includes a chamber 21, a crucible 22, a heater 23, a heat insulating cylinder 24, a shield 25, and a pulling drive unit 26.

The chamber 21 includes a main chamber 211, in which monocrystalline silicon SM is pulled up, and a pull chamber 212 connected to an upper part of the main chamber 211 and configured to house the monocrystalline silicon SM after being pulled up.

The main chamber 211 houses the crucible 22, the heater 23, the heat insulating cylinder 24, and the shield 25.

A gate valve 213 for blocking communication between an upper end of the main chamber 211 and a lower end of the pull chamber 212 is provided at a lower part of the pull chamber 212.

A first gas supply section 214 for supplying inert gas Gf (e.g., argon (Ar) gas) into the pull chamber 212 is provided at an upper part of the pull chamber 212. A first gas discharge section 215 for discharging the inert gas Gf out of the pull chamber 212 is provided at the lower part of the pull chamber 212. A second gas supply section 216 for supplying the inert gas Gf into the chamber 21 is provided at an upper part of the main chamber 211. A second gas discharge section 217 for discharging internal gas Gn (e.g., Ar gas containing evaporant such as SiO generated in the main chamber 211) out of the system of the monocrystalline silicon manufacturing apparatus 2 is provided at a lower part of the main chamber 211.

A charge tube stopper 212A for restricting downward movement of a material feeder 3 described later is provided to the pull chamber 212 at a part above the gate valve 213. The charge tube stopper 212A is a flange-shaped component protruding toward the center of the pull chamber 212 from an entirety of or a plurality of points on an inner wall surface of the pull chamber 212. It should be noted that the charge tube stopper 212A may be provided to the main chamber 211.

The crucible 22 includes an outer graphite crucible and an inner quartz crucible. The crucible 22, which is provided in the main chamber 211, stores a silicon melt M added with a volatile dopant. The crucible 22 is fixed to an upper end of a support shaft 221 that is capable of rotation and upward and downward movement.

The heater 23 is a hollow cylindrical component disposed to surround the crucible 22. The heater 23 is configured to generate heat to melt a silicon material R in the crucible 22.

The heat insulating cylinder 24 is a hollow cylindrical component disposed to surround the heater 23.

The shield 25 is a substantially hollow cylindrical component made of a carbon material. The shield 25, which surrounds the monocrystalline silicon SM that is being pulled up from the silicon melt M, is configured to block radiation heat from the heater 23 to the monocrystalline silicon SM.

The pulling drive unit 26, which is provided at a top of the pull chamber 212, includes a wire 261, a drum 262, a motor 263, and a load cell 264 serving as a weight measurement device.

A seed crystal SC illustrated in FIG. 1 or the material feeder 3 illustrated in FIG. 2 is attached to a first end of the wire 261.

A second end of the wire 261 is fixed to the drum 262 The drum 262, which is provided above the crucible 22, is rotated by driving of the motor 263 to wind and unwind the wire 261 with the wire 261 being kept coaxial with the support shaft 221.

The load cell 264 is configured to detect a load applied on the motor 263 to thereby detect the weight of the monocrystalline silicon SM or the material feeder 3 attached to the first end of the wire 261.

The monocrystalline silicon manufacturing system 1 further includes the material feeder 3.

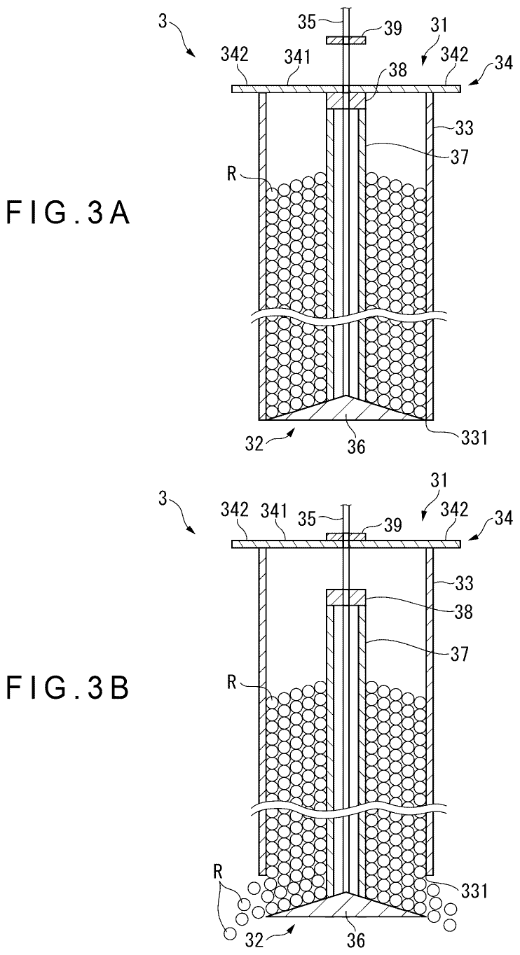

The material feeder 3 is configured to feed a solid silicon material R into the silicon melt M stored in the crucible 22. The material feeder 3 includes a charge tube 31 and an open/close unit 32 as illustrated in FIGS. 3A and 3B. It should be noted that the silicon material R, which is illustrated in a form of spheres for the sake of convenience, actually is not perfect spheres but is in a form of granular mass produced by crushing a polycrystalline silicon material rod.

The charge tube 31 includes a cylindrical portion 33 made of quartz into a form of a hollow cylinder and a metallic charge tube cover 34 in a form of a disk whose diameter is larger than an outer diameter of the cylindrical portion 33.

The charge tube cover 34 is fixed to an upper end of the cylindrical portion 33. A part of the charge tube cover 34 that closes an opening at the upper end of the cylindrical portion 33 defines a closing portion 341. A part of the charge tube cover 34 that protrudes outward from the cylindrical portion 33 defines a protruding portion 342. It should be noted that the protruding portion 342 may be provided on an outer circumferential surface of the cylindrical portion 33.

The open/close unit 32 includes a shaft 35, a bottom cover 36, a guide tube 37, a guide tube cover 38, and a bottom cover stopper 39. The shaft 35, the guide tube cover 38, and the bottom cover stopper 39 are made of metal. The bottom cover 36 and the guide tube 37 are made of quartz.

The shaft 35 penetrates through the closing portion 341 of the charge tube 31 and has an upper end attached to the first end of the wire 261.

The bottom cover 36 is fixed to a lower end of the shaft 35. The bottom cover 36 has a conical shape whose bottom surface diameter is the same as an inner diameter of the cylindrical portion 33, and is configured to close a lower-end opening 331 of the cylindrical portion 33 as illustrated in FIG. 3A and open the lower-end opening 331 as illustrated in FIG. 3B. The bottom cover 36 may have a conical shape whose bottom surface diameter is larger than the inner diameter of the cylindrical portion 33.

The guide tube 37 is in a form of a hollow cylinder covering the shaft 35 within the cylindrical portion 33 to keep the silicon material R from being brought into direct contact with the shaft 35. A lower end of the guide tube 37 is fixed to the bottom cover 36.

The guide tube cover 38, through which the shaft 35 penetrates, closes an upper end of the guide tube 37. The guide tube cover 38 is in contact with a lower surface of the closing portion 341, while the bottom cover 36 closes the lower-end opening 331, thereby restricting the downward movement of the charge tube 31 with respect to the open/close unit 32.

The bottom cover stopper 39 is fixed near the upper end of the shaft 35. As illustrated in FIG. 3B, the bottom cover stopper 39 is in contact with an upper surface of the closing portion 341, thereby restricting the downward movement of the open/close unit 32 with respect to the charge tube 31.

The monocrystalline silicon manufacturing system 1 further includes a control device 4 as illustrated in FIGS. 1 and 2.

The control device 4 is connected to the load cell 264. Weight measurements detected by the load cell 264 are transferred to the control device 4 to be recorded.

The control device 4 is configured to control a first gas supply controller 271 for supplying the inert gas Gf from the first gas supply section 214 into the pull chamber 212, a first gas discharge controller 272 for discharging the inert gas Gf inside the pull chamber 212 through the first gas discharge section 215, a second gas supply controller 273 for supplying the inert gas Gf from the second gas supply section 216 into the chamber 21, a second gas discharge controller 274 for discharging the internal gas Gn inside the chamber 21 through the second gas discharge section 217, a gate valve driver 275 for driving the gate valve 213, a crucible driving unit 276 for rotating the crucible 22, the heater 23, and the motor 263. The control device 4 includes an input unit 41, a display 42, a storage 43, and a control unit 44.

The input unit 41 is provided, for instance, in a form of a touch panel or a physical button, and is configured to output signals corresponding to input operations to the control unit 44.

The display 42 is configured to display various information under the control of the control unit 44.

The storage 43 stores various information relating to feeding of the silicon material R and growth of the monocrystalline silicon SM in a manner readable by the control unit 44.

The control unit 44 provided with a CPU achieves various functions by running programs stored in the storage 43 using the CPU. The control unit 44 includes a feed start controller 45, a feed termination controller 46, and a growth controller 47.

The feed start controller 45 and the feed termination controller 46, which constitute a material feed control device 5, are configured to control the feeding of the silicon material R into the silicon melt M.

The feed start controller 45 feeds the silicon material R into the silicon melt M after lowering the material feeder 3 charged with the silicon material R to a feed position above the silicon melt M. At this time, the feed start controller 45 lowers the open/close unit 32 until the bottom cover stopper 39 is in contact with the closing portion 341 after the protruding portion 342 touches the charge tube stopper 212A, thereby positioning the bottom cover 36 below a lower end position of the cylindrical portion 33 to open the lower-end opening 331.

The feed termination controller 46 judges that the feeding of the silicon material R into the silicon melt M is completed based on the weight detected by the load cell 264. At this time, the feed termination controller 46 raises the open/close unit 32 until the bottom cover stopper 39 and the protruding portion 342 separate from the closing portion 341 and the charge tube stopper 212A, respectively, and judges that the feeding is completed when the weight detected by the load cell 264 matches a predetermined weight. The predetermined weight in the first exemplary embodiment is a self-weight of the material feeder 3.

The growth controller 47 pulls up the seed crystal SC after bringing the seed crystal SC into contact with the silicon melt M to grow the monocrystalline silicon SM. The growth controller 47 receives the detection result of the weight of the currently growing monocrystalline silicon SM from the load cell 264 and adjusts manufacturing conditions so that a final monocrystalline silicon SM of a desired shape can be manufactured.

### Monocrystalline Silicon Manufacturing Method

Next, a monocrystalline silicon manufacturing method will be described below.

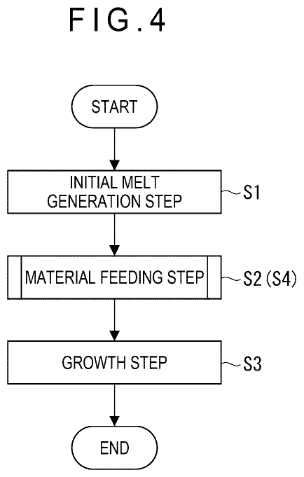

As illustrated in FIG. 4, the growth controller 47 of the control device 4 heats the crucible 22, in which the silicon material R is contained and the silicon melt M is not contained, to generate the silicon melt M (Step S1: initial melt generation step). In the initial melt generation step (Step S1), the gate valve 213 is opened. The inert gas Gf is supplied only from the first gas supply section 214 and the internal gas Gn is discharged only from the second gas discharge section 217, maintaining the inside of the chamber 21 at a reduced pressure.

The material feed control device 5 of the control device 4 performs a material feeding step of feeding the silicon material R into the silicon melt M generated in the initial melt generation step to increase an amount of the silicon melt M in the crucible 22 (Step S2).

The growth controller 47 performs a growth step of growing the monocrystalline silicon SM by pulling up the seed crystal SC after bringing the seed crystal SC into contact with the silicon melt M added with the dopant (Step S3).

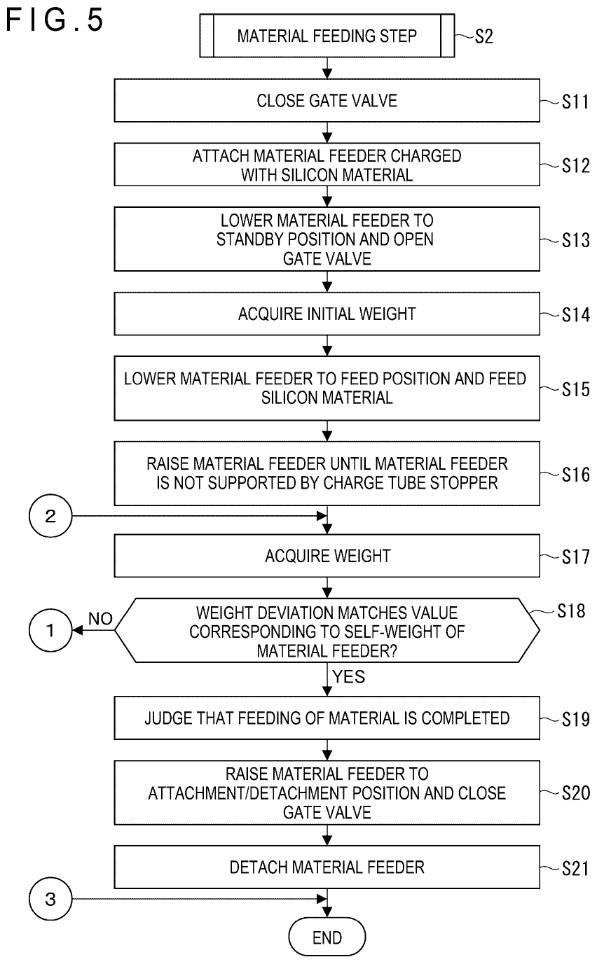

As illustrated in FIG. 5, in the material feeding step (Step S2), the feed start controller 45 of the material feed control device 5 controls the gate valve driver 275 to close the gate valve 213 (Step S11). Through Step S11, the pull chamber 212 is isolated from the main chamber 211 that is in the inert gas atmosphere.

Simultaneously with closing the gate valve 213, the feed start controller 45 controls the second gas supply controller 273 to supply the inert gas Gf into the main chamber 211. The feed start controller 45 controls the first gas supply controller 271 to stop supplying the inert gas Gf into the pull chamber 212.

After bringing the pressure inside the pull chamber 212 into atmospheric pressure, the material feeder 3 charged with the silicon material R is attached to the lower end of the wire 261 at an attachment/detachment position by an operator or a non-illustrated attachment/detachment device (Step S12).

After the material feeder 3 is attached, the feed start controller 45 controls the first gas supply controller 271 to supply the inert gas Gf into the pull chamber 212 and controls the first gas discharge controller 272 to discharge the inert gas Gf inside the pull chamber 212, thereby placing the inside of the pull chamber 212 at a reduced pressure.

The feed start controller 45 drives the motor 263 to lower the material feeder 3 to a standby position above the gate valve 213 and then controls the gate valve driver 275 to open the gate valve 213 (Step S13).

Simultaneously with opening the gate valve 213, the feed start controller 45 controls the second gas supply controller 273 to stop supplying the inert gas Gf into the main chamber 211 from the second gas supply section 216. Further, the feed start controller 45 controls the first gas discharge controller 272 to stop discharging the inert gas Gf through the first gas discharge section 215, and also controls the second gas discharge controller 274 to adjust a gas discharge amount so that the pressure inside the main chamber 211 becomes a pressure suitable for feeding the silicon material R.

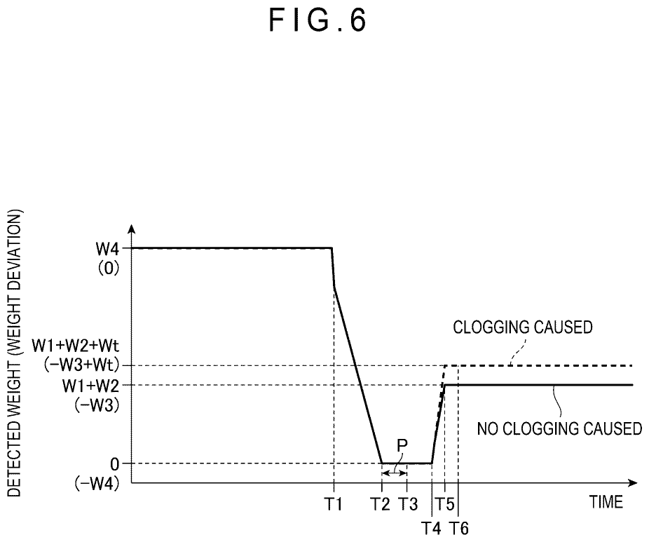

The feed start controller 45 acquires the detection result of the weight detected by the load cell 264 as an initial weight (Step S14). Supposing that a weight of the charge tube 31 is W1, a weight of the open/close unit 32 is W2, and a total weight of the silicon material R charged in the material feeder 3 is W3, the initial weight is a weight W4, which is equal to the sum of the weight W1, the weight W2, and the weight W3 as illustrated in FIG. 6.

It should be noted that the feed start controller 45 may acquire the initial weight before the material feeder 3 is lowered to the standby position, or may acquire the initial weight after the material feeder 3 is lowered to the standby position above the gate valve 213 and before the gate valve 213 is opened.

The feed start controller 45 starts feeding the silicon material R by driving the motor 263 to unwind the wire 261 and lower the material feeder 3 to the feed position (Step S15).

Steps S11 to S15 constitute a feed start process.

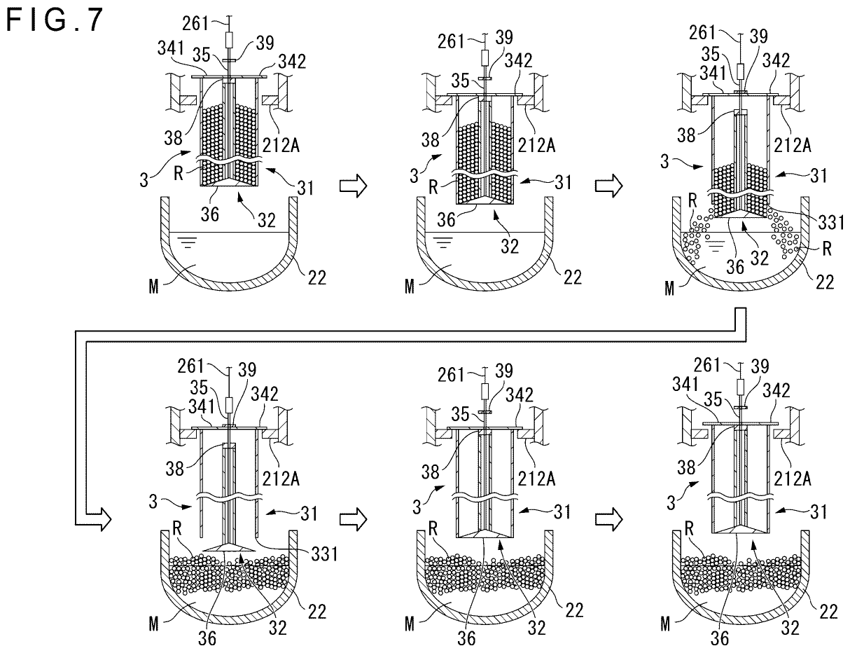

In Step S15, as illustrated in an upper left illustration in FIG. 7, the material feeder 3 starts being lowered while the lower-end opening 331 is closed by the bottom cover 36, the protruding portion 342 separates from the charge tube stopper 212A, and the bottom cover stopper 39 separates from the closing portion 341. When the material feeder 3 is further lowered by further driving the motor 263, the protruding portion 342 touches the charge tube stopper 212A to be stopped thereat and the bottom cover stopper 39 separates from the closing portion 341 at a time T1, as illustrated in an upper center illustration of FIG. 7.

When the motor 263 is further driven from the time T1, only the open/close unit 32 is lowered with the charge tube 31 being supported by the charge tube stopper 212A. The lower-end opening 331 of the charge tube 31 is opened by thus lowering only the open/close unit 32, whereby the silicon material R in the charge tube 31 drops off. In this state, the weight detected by the load cell 264 gradually decreases from the weight W4 as illustrated in FIG. 6.

When the open/close unit 32 is further lowered and the bottom cover stopper 39 is brought into contact with the closing portion 341 at a time T2 as illustrated in an upper right illustration in FIG. 7, where the material feeder 3 reaches the feed position, the feed start controller 45 stops driving the motor 263. In this state, the charge tube 31 and the open/close unit 32 are supported by the charge tube stopper 212A and the charge tube 31, respectively. Accordingly, irrespective of whether the silicon material R remains in the charge tube 31, the weight detected by the load cell 264 becomes zero. A weight deviation with reference to the weight W4 of the material feeder 3 charged with the silicon material R (sometimes simply referred to as the “weight deviation” hereinafter) is −W4 (=0−W4).

When the silicon material R still remains in the charge tube 31, all of the silicon material R in the charge tube 31 is fed to the silicon melt M in accordance with elapse of time as illustrated in a lower left illustration in FIG. 7.

At a time T3, which is a predetermined time elapsed from the time T2, the feed termination controller 46 drives the motor 263 to wind the wire 261 to raise the material feeder 3 until the material feeder 3 is ceased to be supported by the charge tube stopper 212A, as illustrated in FIG. 5 (Step S16).

A standby period P from the time T2 to the time T3 is a period for all of the silicon material R in the material feeder 3 to be assumed to fall into the silicon melt M before the material feeder 3 starts being raised. The standby period P is preferably determined in accordance with a charged amount of the silicon material R. It should be noted that the standby period P may be a period for all of the silicon material R in the material feeder 3 to be assumed to fall into the silicon melt M after the material feeder 3 starts being raised and before the lower-end opening 331 is closed. For instance, if the charged amount of the silicon material R can be assumed to be an amount of all of the silicon material R to fall into the silicon melt M before the lower-end opening 331 is closed even when the open/close unit 32 starts being raised immediately after the bottom cover stopper 39 is in contact with the closing portion 341, the standby period P may be zero seconds. In other words, the open/close unit 32 may start being raised at the time T2.

When the open/close unit 32 is further raised by driving the motor 263 from the time T3, the closing portion 341 is in contact with the guide tube cover 38, the lower-end opening 331 is closed with the bottom cover 36, and the bottom cover stopper 39 separates from the closing portion 341 while the protruding portion 342 is in contact with the charge tube stopper 212A, at a time T4, as illustrated in a lower center illustration of FIG. 7.

When the open/close unit 32 is further raised, the weight detected by the load cell 264 gradually increases.

When the open/close unit 32 is further raised, the protruding portion 342 separates from the charge tube stopper 212A at a time T5, as illustrated in a lower right illustration in FIG. 7.

In this state, when all of the silicon material R charged in the material feeder 3 is fed into the silicon melt M, i.e., when the material feeder 3 is not clogged with the silicon material R, the weight detected by the load cell 264 becomes equal to the sum of the weight W1 and the weight W2, i.e., the self-weight of the material feeder 3, and stays unchanged thereafter, as indicated by a solid line in FIG. 6.

Meanwhile, it sometimes occurs that a plurality of grains of the silicon material R are jammed between the lower-end opening 331 and the bottom cover 36 to cause clogging by the silicon material R, so that the silicon material R remains within the material feeder 3. In this case, supposing that a total weight of the silicon material R remained within the material feeder 3 is Wt, the weight detected by the load cell 264 becomes equal to the sum of the weight W1, the weight W2, and the weight Wt, i.e., a weight larger than the self-weight of the material feeder 3, and stays unchanged thereafter, as indicated by a broken line in FIG. 6.

After the time T5 onwards, the weight deviation is as follows.

$$Clogging caused : - W 3 + Wt ( = W 1 + W 2 + W t - W 4 )$$

$$No clogging caused : - W 3 ( = W 1 + W 2 - W 4 )$$

At a time T6, which is a predetermined time elapsed from the time T5, the feed termination controller 46 acquires the detection result of the weight detected by the load cell 264 as illustrated in FIG. 5 (Step S17).

The feed termination controller 46 judges whether the weight deviation matches a value corresponding to the self-weight of the material feeder 3, i.e., the predetermined weight (Step S18).

When judging that the weight deviation matches the value corresponding to the self-weight of the material feeder 3 (Step S18: YES), the feed termination controller 46 judges that the feeding of the silicon material R is completed (Step S19).

The feed termination controller 46 then drives the motor 263 to raise the material feeder 3 to the attachment/detachment position and then controls the gate valve driver 275 to close the gate valve 213 (Step S20).

Steps S16 to S20 constitute a feed termination process.

Simultaneously with closing the gate valve 213, the feed start controller 46 controls the second gas supply controller 273 to supply the inert gas Gf into the main chamber 211. The feed termination controller 46 controls the first gas supply controller 271 to stop supplying the inert gas Gf into the pull chamber 212.

After the pressure inside the pull chamber 212 is brought into atmospheric pressure, the material feeder 3 is detached from the wire 261 by an operator or the attachment/detachment device (Step S21).

Thereafter, a non-illustrated dopant adding device is attached to the wire 261 by an operator or the attachment/detachment device to add the dopant into the silicon melt M. Subsequently, the seed crystal SC is attached to the wire 261 by an operator or the attachment/detachment device in place of the dopant adding device to perform the growth step of Step S3.

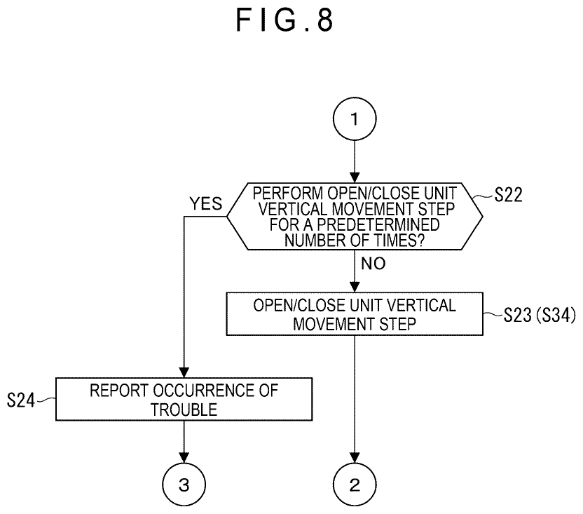

In contrast, when judging that the weight deviation does not match the value corresponding to the self-weight of the material feeder 3 (Step S18: NO), and judging that the silicon material R is jammed between the lower-end opening 331 and the bottom cover 36, the feed termination controller 46 performs an open/close unit vertical movement step described later, where the open/close unit 32 is upwardly and downwardly moved to eliminate the clogged silicon material R. The feed termination controller 46 judges whether the open/close unit vertical movement step is performed for a predetermined number of times, as illustrated in FIG. 8 (Step S22). The predetermined number of times, which is not specifically limited, is set at a number capable for the clogged silicon material R to be eliminated by the open/close unit vertical movement step.

When judging that the open/close unit vertical movement step has not been performed for the predetermined number of times (Step S22: NO), the feed termination controller 46 performs additional open/close unit vertical movement step(s) (Step S23).

In the open/close unit vertical movement step of Step S23, for instance, the feed termination controller 46 controls the motor 263 to lower the open/close unit 32 to open the lower-end opening 331 of the charge tube 31 and subsequently raises the open/close unit 32, as illustrated in the upper right illustration in FIG. 7. At this time, the open/close unit 32 may be raised after the bottom cover stopper 39 is in contact with the closing portion 341 or, alternatively, before the bottom cover stopper 39 is in contact with the closing portion 341. In Step S23, a size of a gap created by opening the lower-end opening 331 is changed once or more.

The feed termination controller 46 acquires the detection result of the weight detected by the load cell 264 after Step S23, as illustrated in FIG. 5 (Step S17).

In contrast, when judging that the open/close unit vertical movement step is performed for the predetermined number of times (Step S22: YES), the feed termination controller 46 reports that a trouble has occurred, i.e., the clogging has not been eliminated (Step S24), and terminates the material feeding step as illustrated in FIG. 5.

In Step S24, the feed termination controller 46, for instance, displays a screen showing occurrence of the trouble on the display 42 or outputs sound indicating the occurrence of the trouble from a non-illustrated speaker. An operator, who recognizes the occurrence of the trouble, for instance, switches the mode of the monocrystalline silicon manufacturing system 1 to a manual operation and detaches the material feeder 3 from the wire 261.

It should be noted that, after reporting the occurrence of the trouble in Step S24, the feed termination controller 46 may perform Step S20 to raise the material feeder 3 to the attachment/detachment position without switching the mode of the monocrystalline silicon manufacturing system 1 to a manual operation.

### Advantage(s) of First Exemplary Embodiment

The following advantages can be achieved by the first exemplary embodiment.

(1) The material feed control device 5 feeds the silicon material R into the silicon melt M by lowering the open/close unit 32 of the material feeder 3 with respect to the charge tube 31 to open the lower-end opening 331, and judges that the feeding of the silicon material R is completed based on the detection result of the load cell 264. Specifically, the material feed control device 5 lowers the open/close unit 32 until the bottom cover stopper 39 is in contact with the closing portion 341 after the protruding portion 342 touches the charge tube stopper 212A, and then raises the open/close unit 32 until the bottom cover stopper 39 and the protruding portion 342 separate from the closing portion 341 and the charge tube stopper 212A, respectively. Then, the material feed control device 5 judges that the feeding of the silicon material R is completed when the weight deviation matches the value corresponding to the self-weight of the material feeder 3.

Accordingly, it is not necessary for an operator to visually check the material feeder 3, thereby avoiding increase in the workload for monitoring and deviation in determination results due to the operator's sensory evaluation. Further, even when the cylindrical portion 33 of the charge tube 31 is clouded, the feeding completion of the silicon material R can be appropriately judged.

(2) The material feed control device 5 performs the open/close unit vertical movement step when the weight deviation does not match the value corresponding to the self-weight of the material feeder 3 due to jamming of the silicon material R.

Accordingly, even when the silicon material R is jammed, all of the silicon material R can be fed into the silicon melt M.

(3) The material feed control device 5 reports occurrence of a trouble when the weight deviation does not match the value corresponding to the self-weight of the material feeder 3 even after a step of judging whether the feeding of the silicon material R is completed based on the detection result of the load cell 264 and the open/close unit vertical movement step are each performed for a predetermined number of times.

Accordingly, an operator can rapidly perform a restoration operation.

(4) The material feed control device 5 judges whether the feeding of the silicon material R is completed using the load cell 264 for detecting the weight of the monocrystalline silicon SM that is being grown.

Accordingly, the monocrystalline silicon manufacturing system 1 needs not be provided with a weight detector dedicated for judging the feeding completion of the silicon material R, so that the structure of the monocrystalline silicon manufacturing system 1 can be simplified.

### Second Exemplary Embodiment

### Arrangement of Monocrystalline Silicon Manufacturing System

Next, an arrangement of a monocrystalline silicon manufacturing system according to a second exemplary embodiment of the invention will be described below.

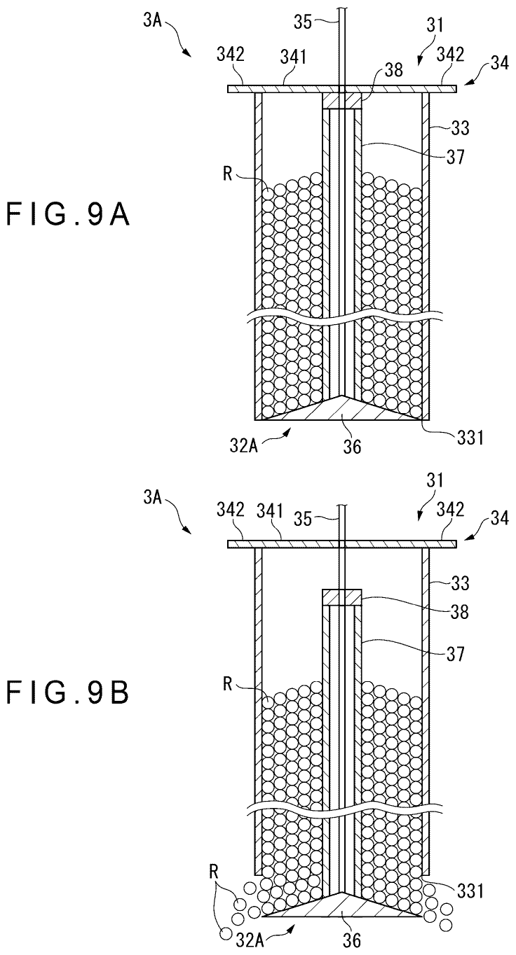

A monocrystalline silicon manufacturing system 1A according to the second exemplary embodiment as illustrated in FIG. 1 is different from the monocrystalline silicon manufacturing system 1 according to the first exemplary embodiment in terms of a structure of a control device 4A of the monocrystalline silicon manufacturing apparatus 2 and a material feeder 3A illustrated in FIGS. 9A and 9B. The same components as those in the first exemplary embodiment will be denoted by the same reference signs and names to simplify or omit explanation of the components.

The material feeder 3A is different from the material feeder 3 of the first exemplary embodiment in terms of the presence of an open/close unit 32A in place of the open/close unit 32.

The open/close unit 32A is different from the open/close unit 32 of the first exemplary embodiment in that the bottom cover stopper 39 is not provided. Downward movement of thus configured open/close unit 32A with respect to the charge tube 31 is not restricted unlike the open/close unit 32 of the first exemplary embodiment.

As illustrated in FIGS. 1 and 2, a control unit 44A, which is a part of the control device 4A, includes a feed start controller 45A, a feed termination controller 46A, and the growth controller 47.

The feed start controller 45A and the feed termination controller 46A, which constitute a material feed control device 5A, are configured to control the feeding of the silicon material R into the silicon melt M.

The feed start controller 45A feeds the silicon material R into the silicon melt M after lowering the material feeder 3A charged with the silicon material R to the feed position. At this time, the feed start controller 45A lowers the open/close unit 32A until the size of the gap created by opening the lower-end opening 331 reaches a predetermined value after the protruding portion 342 is in contact with the charge tube stopper 212A.

The feed termination controller 46A judges that the feeding of the silicon material R into the silicon melt M is completed based on the weight detected by the load cell 264. At this time, the feed termination controller 46A judges that the feeding is completed when the weight detected by the load cell 264 matches a predetermined weight while the open/close unit 32A is not raised. The predetermined weight in the second exemplary embodiment is the self-weight of the open/close unit 32A.

### Monocrystalline Silicon Manufacturing Method

Next, a monocrystalline silicon manufacturing method will be described below.

The same steps as those in the first exemplary embodiment will be denoted by the same reference signs and names to simplify or omit explanation of the steps.

As illustrated in FIG. 4, the monocrystalline silicon manufacturing method according to the second exemplary embodiment is different from the monocrystalline silicon manufacturing method of the first exemplary embodiment in that a material feeding step of Step S4 is performed in place of the material feeding step of Step S2.

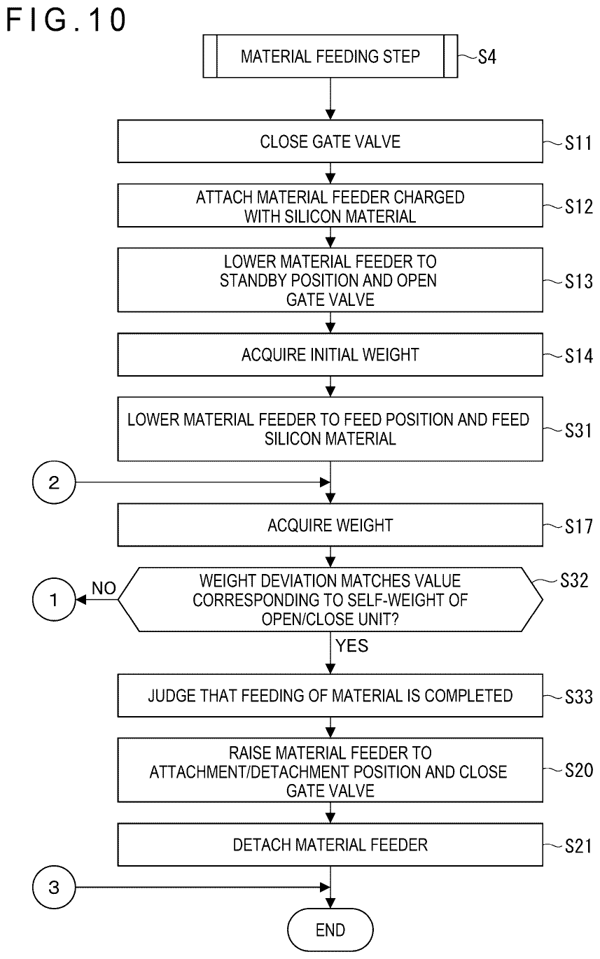

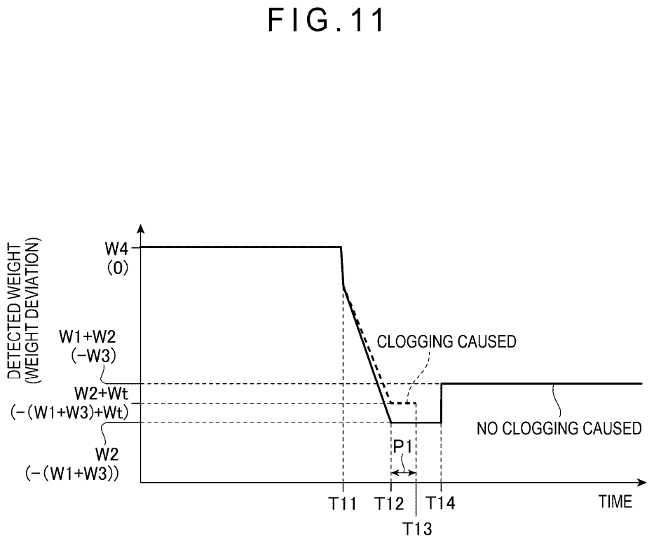

As illustrated in FIG. 10, in the material feeding step of Step S4, Steps S11 to S13 in the first exemplary embodiment are performed. After Step S13, the feed start controller 45A of the material feed control device 5A acquires the detection result of the weight detected by the load cell 264 as an initial weight (Step S14). Supposing that the weight of the charge tube 31 is W1, the weight of the open/close unit 32A is W2, and a total weight of the silicon material R charged in the material feeder 3A is W3, the initial weight is a weight W4, which is equal to the sum of the weight W1, the weight W2, and the weight W3, as illustrated in FIG. 11.

The feed start controller 45A starts feeding the silicon material R by driving the motor 263 to lower the material feeder 3A to the feed position, where the downward movement of the material feeder 3A is restricted by the charge tube stopper 212A and the lower-end opening 331 is opened (Step S31).

Steps S11 to S14 and S31 constitute a feed start process.

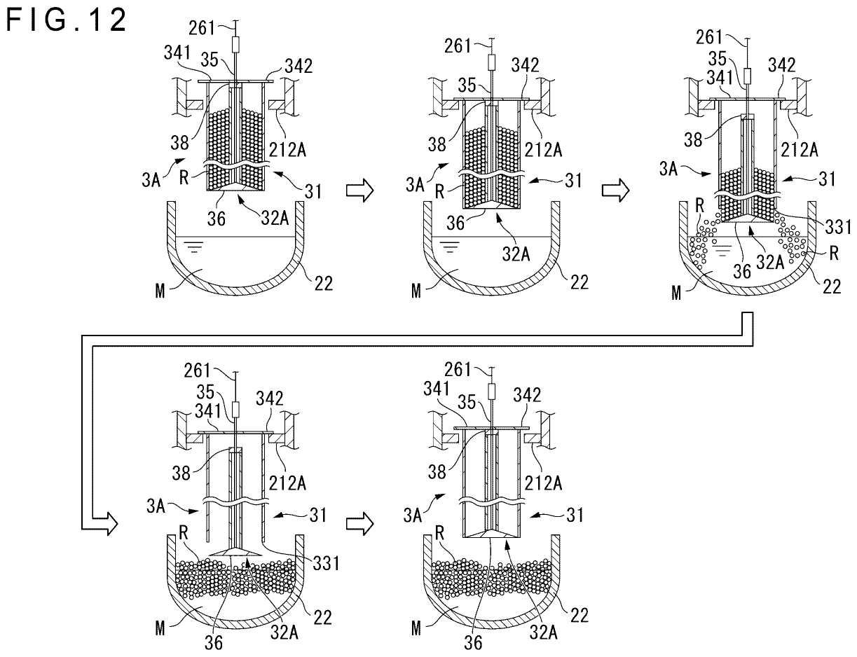

In Step S31, as illustrated in an upper left illustration in FIG. 12, the material feeder 3A starts being lowered while the lower-end opening 331 is closed by the bottom cover 36 and the protruding portion 342 separates from the charge tube stopper 212A. When the material feeder 3A is further lowered by further driving of the motor 263, the protruding portion 342 touches the charge tube stopper 212A at a time T11, as illustrated in an upper center illustration in FIG. 12.

When the motor 263 is further driven from the time T11, only the open/close unit 32A is lowered while the charge tube 31 is supported by the charge tube stopper 212A. When the open/close unit 32A of the material feeder 3A reaches a feed position where the size of the gap created by opening the lower-end opening 331 become a predetermined value as illustrated in an upper right illustration in FIG. 12, the feed start controller 45A stops driving the motor 263. When the lower-end opening 331 of the charge tube 31 is opened, the silicon material R inside the charge tube 31 drops off, whereby the weight detected by the load cell 264 gradually decreases from the weight W4 as illustrated in FIG. 11. When all of the silicon material R charged in the material feeder 3A is fed into the silicon melt M at a time T12 as illustrated in a lower left illustration in FIG. 12, the weight detected by the load cell 264 becomes equal to the weight W2, i.e., the self-weight of the open/close unit 32A, and stays unchanged thereafter, as indicated by a solid line in FIG. 11.

Meanwhile, it sometimes occurs that the silicon material R is jammed between the lower-end opening 331 and the bottom cover 36 to cause clogging by the silicon material R, so that the silicon material R remains within the material feeder 3A. In this case, supposing that the total weight of the silicon material R remained within the material feeder 3A is Wt, the weight detected by the load cell 264 after the time T12 becomes equal to the sum of the weight W2 and the weight Wt, i.e., a weight larger than the self-weight of the open/close unit 32A, and stays unchanged thereafter, as indicated by a broken line in FIG. 11.

After the time T12 onwards, the weight deviation while the open/close unit 32A is stopped is as follows.

$$Clogging caused : - ( W 1 + W 3 ) + Wt ( = W 2 + W t - W 4 )$$

$$No clogging caused : - ( W 1 + W 3 ) ( = W 2 - W 4 )$$

At a time T13, which is a predetermined time elapsed from the time T12, the feed termination controller 46A acquires the detection result of the weight detected by the load cell 264 as illustrated in FIG. 10 (Step S17).

A standby period P1 from the time T12 to the time T13 is defined in the same manner as the standby period P in the first exemplary embodiment, and may be zero seconds.

The feed termination controller 46A judges whether the weight deviation matches a value corresponding to the self-weight of the open/close unit 32A, i.e., a value corresponding to the predetermined weight (Step S32).

When judging that the weight deviation matches the value corresponding to the self-weight of the open/close unit 32A (Step S32: YES), the feed termination controller 46A judges that the feeding of the silicon material R is completed (Step S33).

The feed termination controller 46A, for instance, drives the motor 263 at a time T14 to raise the material feeder 3A to the attachment/detachment position and then controls the gate valve driver 275 to close the gate valve 213 (Step S20).

Steps S17, S32, S33, and S20 constitute a feed termination process.

When the open/close unit 32A is further raised by driving the motor 263, the protruding portion 342 separates from the charge tube stopper 212A as illustrated in a lower right illustration in FIG. 12. The weight subsequently detected by the load cell 264 is equal to the sum of the weight W1 and the weight W2, i.e., the self-weight of the material feeder 3A, as indicated by a solid line in FIG. 11. The weight deviation at this time is-W3.

Subsequently, after Step S21 of the first exemplary embodiment is performed, the growth step of Step S3 is performed.

In contrast, when judging that the weight deviation does not match the value corresponding to the self-weight of the open/close unit 32A (Step S32: NO), the feed termination controller 46A judges whether the open/close unit vertical movement step is performed for a predetermined number of times as illustrated in FIG. 8 (Step S22).

When judging that the open/close unit vertical movement step is not performed for the predetermined number of times (Step S22: NO), the feed termination controller 46A performs additional open/close unit vertical movement step(s) (Step S34).

In the open/close unit vertical movement step of Step S34, for instance, the feed termination controller 46A may control the motor 263 to lower and subsequently raise the open/close unit 32A or, alternatively, raise and subsequently lower the open/close unit 32A, from the state illustrated in the lower left illustration in FIG. 12. In Step S34, the size of the gap created by opening the lower-end opening 331 is changed once or more.

The feed termination controller 46A acquires the detection result of the weight detected by the load cell 264 after Step S34 as illustrated in FIG. 10 (Step S17).

In contrast, when judging that the open/close unit vertical movement step is performed for the predetermined number of times (Step S22: YES), the feed termination controller 46A reports occurrence of a trouble (Step S24), and terminates the material feeding step as illustrated in FIG. 10.

### Advantage(s) of Second Exemplary Embodiment

The following advantages can be achieved by the second exemplary embodiment in addition to the advantages (2) to (4) in the first exemplary embodiment.

(5) The material feed control device 5A feeds the silicon material R into the silicon melt M by lowering the open/close unit 32A to open the lower-end opening 331 after the protruding portion 342 is in contact with the charge tube stopper 212A, and judges that the feeding of the silicon material R is completed when the weight deviation matches the value corresponding to the self-weight of the open/close unit 32A while the open/close unit 32A is not raised.

Accordingly, the feeding completion of the silicon material R can be easily and appropriately judged for the same reason as (1) in the first exemplary embodiment.

### Modifications

The feeding completion of the silicon material R is judged based on the weight deviation in the first exemplary embodiment. However, the feeding completion may be judged based on whether the detection result of the load cell 264 matches the self-weight of the material feeder 3 in Step S18 without acquiring the initial weight in Step S14. Similarly, in the second exemplary embodiment, the feeding completion of the silicon material R may be judged based on whether the detection result of the load cell 264 matches the self-weight of the open/close unit 32A in Step S32 without acquiring the initial weight in Step S14.

In the first and second exemplary embodiments, when it is judged that the weight deviation does not match the value corresponding to the predetermined weight (the self-weight of the material feeder 3 or the open/close unit 32A) in Step S18 or S32 firstly performed, occurrence of a trouble may be reported in Step S24 without performing the open/close unit vertical movement step of Step S23 or S34, or alternatively, the material feeder 3 or 3A may be raised to the attachment/detachment position by performing Step S20.

In the first and second exemplary embodiments, when it is judged that the open/close unit vertical movement step is performed for the predetermined number of times in Step S22, the material feeder 3 or 3A may be raised to the attachment/detachment position by performing Step S20 without reporting the occurrence of the trouble in Step S24.

In the first and second exemplary embodiments, monocrystalline silicon SM added with no dopant may be manufactured.

While the load cell 264 for detecting the weight of the monocrystalline silicon SM that is being grown is used to judge the feeding completion of the silicon material R, a weight detector other than the load cell 264 may be used. Examples of such a weight detector include a weight gauge on which the drum 262 is placed.

What is claimed is:

1. A material feeding method of feeding a silicon material into a silicon melt in a crucible provided within a chamber using a material feeder, the material feeder including a charge tube and an open/close unit, the charge tube having a hollow cylindrical shape, the open/close unit being configured to open and close a lower-end opening of the charge tube, the material feeding method comprising:
starting feeding of the silicon material, by attaching the material feeder charged with the silicon material to a first end of a wire and lowering the open/close unit with respect to the charge tube to open the lower-end opening to feed the silicon material into the silicon melt; and
judging completion of the feeding of the silicon material based on a weight of the material feeder attached to the first end of the wire, to terminate the feeding of the silicon material, the weight being detected by a weight detector.

2. The material feeding method according to claim 1, wherein
the charge tube includes a cylindrical portion provided with the lower-end opening, a closing portion configured to close an upper end of the cylindrical portion, and a protruding portion protruding from an outer circumferential surface of the cylindrical portion or the closing portion,
the open/close unit includes a shaft penetrating through the closing portion and having an upper end attached to the first end of the wire, and a bottom cover fixed to a lower end of the shaft and configured to open and close the lower-end opening,
the chamber is provided with a charge tube stopper configured to be in contact with a lower end of the protruding portion to restrict a downward movement of the charge tube, and
in the starting the feeding, the open/close unit is lowered with respect to the charge tube to open the lower-end opening to feed the silicon material, after the protruding portion is brought into contact with the charge tube stopper.

3. The material feeding method according to claim 2, wherein
the shaft is provided with a bottom cover stopper configured to be in contact with an upper end of the closing portion to restrict a downward movement of the bottom cover with respect to the charge tube,
in the starting the feeding, the open/close unit is lowered to feed the silicon material after the protruding portion is brought into contact with the charge tube stopper until the bottom cover stopper is in contact with the closing portion,
in the judging the completion of the feeding to terminate the feeding, the open/close unit is raised until the bottom cover stopper separates from the closing portion and the protruding portion separates from the charge tube stopper, and the feeding of the silicon material is judged to be completed when a detection result of the weight detected by the weight detector matches a predetermined weight, and
the predetermined weight is a self-weight of the material feeder.

4. The material feeding method according to claim 2, wherein
in the judging the completion of the feeding to terminate the feeding, the feeding of the silicon material is judged to be completed when a detection result of the weight detected by the weight detector matches a predetermined weight while the open/close unit is not raised, and
the predetermined weight is a self-weight of the open/close unit.

5. The material feeding method according to claim 3, wherein
when the detection result of the weight does not match the predetermined weight in the judging the completion of the feeding to terminate the feeding, the judging the completion of the feeding to terminate the feeding is performed, after performing an open/close unit vertical movement in which the open/close unit is upwardly and downwardly moved.

6. The material feeding method according to claim 5, wherein
occurrence of a trouble is reported when the detection result of the weight does not match the predetermined weight even after performing each of the judging the completion of the feeding to terminate the feeding and the open/close unit vertical movement for a predetermined number of times.

7. The material feeding method according to claim 1, wherein
a drum configured to be rotated by driving of a motor to wind or unwind the wire is fixed to a second end of the wire,
the weight detector is a load cell configured to detect a load applied on the motor to detect the weight of the material feeder attached to the first end of the wire, and
in the starting the feeding and the judging the completion of the feeding to terminate the feeding, the motor is controlled to move the material feeder.

8. A monocrystalline silicon manufacturing method comprising:
feeding the silicon material into the silicon melt by the material feeding method according to claim 1; and
growing monocrystalline silicon using the silicon melt by CZ method.

9. A material feed control device configured to feed a silicon material into a silicon melt in a crucible provided within a chamber using a material feeder, the material feeder including a charge tube and an open/close unit, the charge tube having a hollow cylindrical shape, the open/close unit being configured to open and close a lower-end opening of the charge tube, the material feed control device comprising:
a feed start controller configured to lower the open/close unit of the material feeder, which is charged with the silicon material and attached to a first end of a wire, with respect to the charge tube to open the lower-end opening to feed the silicon material into the silicon melt; and
a feed termination controller configured to judge completion of feeding of the silicon material based on a weight of the material feeder attached to the first end of the wire, the weight being detected by a weight detector.

10. The material feed control device according to claim 9, wherein
the charge tube includes a cylindrical portion provided with the lower-end opening, a closing portion configured to close an upper end of the cylindrical portion, and a protruding portion protruding from an outer circumferential surface of the cylindrical portion or the closing portion,
the open/close unit includes a shaft penetrating through the closing portion and having an upper end attached to the first end of the wire, and a bottom cover fixed to a lower end of the shaft and configured to open and close the lower-end opening,
the chamber is provided with a charge tube stopper configured to be in contact with a lower end of the protruding portion to restrict a downward movement of the charge tube, and
the feed start controller is configured to lower the open/close unit with respect to the charge tube to open the lower-end opening to feed the silicon material, after the protruding portion is brought into contact with the charge tube stopper.

11. The material feed control device according to claim 10, wherein
the shaft is provided with a bottom cover stopper configured to be in contact with an upper end of the closing portion to restrict a downward movement of the bottom cover with respect to the charge tube,
the feed start controller is configured to lower the open/close unit to feed the silicon material after the protruding portion is brought into contact with the charge tube stopper until the bottom cover stopper is in contact with the closing portion,
the feed termination controller is configured to raise the open/close unit until the bottom cover stopper separates from the closing portion and the protruding portion separates from the charge tube stopper, and judge that the feeding of the silicon material is completed when a detection result of the weight detected by the weight detector matches a predetermined weight, and
the predetermined weight is a self-weight of the material feeder.

12. The material feed control device according to claim 10, wherein
the feed termination controller is configured to judge that the feeding of the silicon material is completed when a detection result of the weight detected by the weight detector matches a predetermined weight while the open/close unit is not raised, and
the predetermined weight is a self-weight of the open/close unit.

13. The material feed control device according to claim 11, wherein
when judging that the detection result of the weight does not match the predetermined weight, the feed termination controller performs judgment of whether the feeding of the silicon material is completed based on the detection result of the weight, after performing an open/close unit vertical movement in which the open/close unit is upwardly and downwardly moved.

14. The material feed control device according to claim 13, wherein
the feed termination controller is configured to report occurrence of a trouble when the detection result of the weight does not match the predetermined weight even after performing each of the judgment of whether the feeding of the silicon material is completed and the open/close unit vertical movement for a predetermined number of times.

15. The material feed control device according to claim 9, wherein
a drum configured to be rotated by driving of a motor to wind or unwind the wire is fixed to a second end of the wire,
the weight detector is a load cell configured to detect a load applied on the motor to detect the weight of the material feeder attached to the first end of the wire, and
the feed start controller and the feed termination controller are configured to control the motor to move the material feeder.

16. A monocrystalline silicon manufacturing system comprising:
the material feed control device according to claim 9;
the material feeder;
the wire attached with the material feeder or a seed crystal at the first end;
the weight detector; and
a growth controller configured to bring the seed crystal attached to the first end of the wire into contact with the silicon melt and then pull up the seed crystal to grow monocrystalline silicon by CZ method.

17. A monocrystalline silicon manufacturing system comprising:
the material feed control device according to claim 15;
the material feeder;
a pulling drive unit including the wire attached with the material feeder or a seed crystal at the first end, the drum, and the motor;
the load cell; and
a growth controller configured to bring the seed crystal attached to the first end of the wire into contact with the silicon melt and then pull up the seed crystal to grow monocrystalline silicon by CZ method.
